(19) United States
(12) Patent Application Publication
(10) Pub. No.: US 2008/0131981 A1
(43) Pub. Date: Jun. 5, 2008

(54) Method for forming Au-bump with clean surface

(76) Inventors: Shih-Hsiung Lin, Hsin-Chu (TW); Po-Jui Chen, Hsinchu (TW); Jian-Hong Liu, Hsinchu (TW)

Correspondence Address: NORTH AMERICA INTELLECTUAL PROPERTY CORPORATION, P.O. BOX 506, MERRIFIELD, VA, 22116, US

(21) Appl. No.: 11/950,358

(22) Filed: Dec. 4, 2007

Related U.S. Application Data
(60) Provisional application No. 60/868,356, filed on Dec. 4, 2006.

(51) Int. Cl. H01L 21/66

(52) U.S. Cl. 438/17; 257/E21.531

(57) ABSTRACT

A method for fabricating and testing a semiconductor wafer includes sputtering a TiW layer on a passivation layer and on pads, next sputtering a seed layer, made of gold, on the TiW layer, next forming a photoresist layer on the seed layer, next electroplating gold bumps on the seed layer exposed by openings in the photoresist layer, next removing the photoresist layer, next removing the seed layer not under the gold bumps, next etching the TiW layer not under the gold bumps with an etchant containing H₂O₂ at a temperature of between 35 and 50 degrees C, or with an etchant containing H₂O₂ and with ultrasonic waves applied to the etchant, next contacting probe tips of a probe card with some of the gold bumps, next cleaning the probe tips until repeating the step of contacting the probe tips with some of the gold bumps at greater than 100 times, and then after cleaning the probe tips, repeating the step of contacting the probe tips with some of the gold bumps.

This application claims priority to U.S. provisional application No. 60/868,356, filed on Dec. 4, 2006, which is herein incorporated by reference in its entirety.

### BACKGROUND OF THE INVENTION

1. Field of the Invention

The invention relates to a method for forming and tesing a semiconductor wafer, by which the frequency of cleaning test probes is significantly reduced, and, more specifically, to a method for forming and testing a semiconductor wafer, by which the residual of titanium oxide and tungsten oxide remaining on gold bumps of the semiconductor wafer can be reduced, and the chance of the residual stuck onto the test probes can be diminished.

2. Brief Description of the Related Art

Titanium-tungsten alloy is one of barrier-type metals treated as an adhesion/barrier layer to prevent the occurrence of interdiffusion in semiconductor connector. Titanium-tungsten film, of 10%Ti and 90%W by weight, is layered onto a substrate under a sputtered gold film as a seed layer for following a plating process.

Electroplating provides the electrochemical reaction to deposit Au onto the seed layer with a covered layer of patterned photoresist. Then, the continuous seed layer and UBM layer have necessary to completely remove by the Au etching and TiW etching sequentially in order to prevent interbumps connection electrically.

However, it always results from a residual problem to the TiW surrounded Au Bumps with this set of etching process. The significant amount of residue that is discontinuously distributed throughout all of the bumps presents a shape in elliptic or sheet-like within an order of magnitude of 100 nm. The presence of residue over bumps will cause a contamination problem to the following chip probing test of bumped wafers.

The test probes may be needed to make the electrical contact with Au bumps in order to thoroughly analyze a chip circuit. Thus, the probe heads often undergo residue remaining on Au bumps and the test probes, if contaminated, need to be cleaned by cleaning sheets during chip probing (CP) test. As above description, analysis misses without cleaning tips of test probes could happen after a number of probe touchdowns. As a result, a chip probing retest need to be carrid out, if required, due to the low reliability in the probing test.

A frequent cleaning cycle to the test probes is necessary, and thus time cost increases to a proprietor. Moreover, the great amount of residue on the rough surface of Au bumps has been found experimentally.

### SUMMARY OF THE INVENTION

It is the objective of the invention to provide a method to reduce the residual of titanium oxide and tungsten oxide remaining on gold bumps of a semiconductor wafer.

It is the objective of the invention to provide a method to reduce a frequcecy of cleaning test probes during a chip probing (CP) test.

In order to reach the above objectives, a method for fabricating and testing a semiconductor wafer comprises the following steps: providing a silicon substrate, multiple metal oxide semiconductor (MOS) devices in or over said silicon substrate, a first dielectric layer over said silicon substrate, a metallization structure over said first dielectric layer, wherein said metallization structure comprises a first metal layer and a second metal layer over said first metal layer, and wherein said metallization structure is connected to said multiple metal oxide semiconductor devices, a second dielectric layer between said first and second metal layers, and a passivation layer over said metallization structure, over said first and second dielectric layers and over said multiple metal oxide semiconductor devices, multiple first openings in said passivation layer exposing multiple pads of said metallization structure, respectively, sputtering a titanium-tungsten-alloy layer on said passivation layer and over said multiple pads exposed by said multiple first openings, sputtering a gold layer on said titanium-tungsten-alloy layer, forming a photoresist layer on said gold layer, multiple second openings in said photoresist layer exposing said gold layer, electroplating multiple gold bumps with a thickness of between 9 and 30 micrometers on said gold layer exposed by said multiple second openings, removing said photoresist layer, removing said gold layer not under said multiple gold bumps, etching said titanium-tungsten-alloy layer not under said multiple gold bumps with an etchant containing hydrogen peroxide at a temperature of between 35 and 50 degrees C., contacting multiple probe tips of a probe card with some of said multiple gold bumps to probe said semiconductor wafer, cleaning said multiple probe tips of said probe card until repeating the step of said contacting said multiple probe tips of said probe card with some of said multiple gold bumps at greater than 100 times, and after said cleaning said probe tips of said probe card, repeating the step of said contacting said multiple probe tips of said probe card with some of said multiple gold bumps.

In order to reach the above objectives, a method for fabricating and testing a semiconductor wafer comprises the following steps: providing a silicon substrate, multiple metal oxide semiconductor (MOS) devices in or over said silicon substrate, a first dielectric layer over said silicon substrate, a metallization structure over said first dielectric layer, wherein said metallization structure comprises a first metal layer and a second metal layer over said first metal layer, and wherein said metallization structure is connected to said multiple metal oxide semiconductor devices, a second dielectric layer between said first and second metal layers, and a passivation layer over said metallization structure, over said first and second dielectric layers and over said multiple metal oxide semiconductor devices, multiple first openings in said passivation layer exposing multiple pads of said metallization structure, respectively, sputtering a titanium-tungsten-alloy layer on said passivation layer and over said multiple pads exposed by said multiple first openings, sputtering a gold layer on said titanium-tungsten-alloy layer, forming a photoresist layer on said gold layer, multiple second openings in said photoresist layer exposing said gold layer, electroplating multiple gold bumps with a thickness of between 9 and 30 micrometers on said gold layer exposed by said multiple second openings, removing said photoresist layer, removing said gold layer not under said multiple gold bumps, etching said titanium-tungsten-alloy layer not under said multiple gold bumps with an etchant containing hydrogen peroxide and with an ultrasonic wave applied to said etchant, contacting multiple probe tips of a probe card with some of said multiple gold bumps to probe said semiconductor wafer, cleaning said multiple probe tips of said probe card until repeating the step of said contacting said multiple probe tips of said probe card with some of said multiple gold bumps at greater than 100 times, and after said cleaning said probe tips of said probe card, repeating the step of said contacting said multiple probe tips of said probe card with some of said multiple gold bumps.

To enable the objectives, technical contents, characteristics and accomplishments of the present invention, the embodiments of the present invention are to be described in detail in copperation with the attached drawings below.

### BRIEF DESCRIPTION OF THE DRAWINGS

FIG. 1 is a cross-sectional view schematically showing a wafer according to the present invention.

FIGS. 2A through 2H and FIG. 2J are cross-sectional views showing a process for fabricating multiple gold bumps and electrically testing dies according to one embodiment of the present invention.

FIG. 2I is a top view showing a semiconductor wafer with multiple gold bumps.

### DETAILED DESCRIPTION OF THE INVENTION

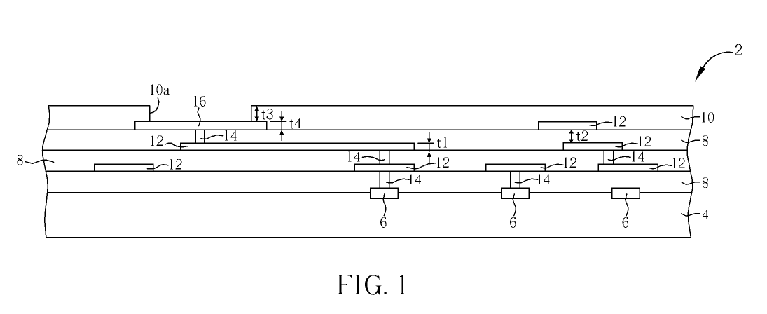

Referring to FIG. 1, a semiconductor wafer 2 includes a semiconductor substrate 4, multiple semiconductor devices 6, a metallization structure, multiple dielectric layers 8 and a passivation layer 10. The semiconductor substrate 4 may be a silicon substrate.

The semiconductor devices 6 are formed in or over the semiconductor substrate 4. The semiconductor device 6 may be a memory device, a logic device, a passive device, such as resistor, capacitor, inductor or filter, or an active device, such as p-channel MOS device, n-channel MOS device, CMOS (Complementary Metal Oxide Semiconductor), BJT (Bipolar Junction Transistor) or BiCMOS (Bipolar CMOS) device.

The metallization structure, circuit structure, is formed over the semiconductor substrate 4, connected to the semiconductor devices 6. The metallization structure comprises multiple patterned metal layers 12 having a thickness t1 of less than 3 micrometers (such as between 0.2 and 2 μm) and multiple metal plugs 14. For example, the patterned metal layer 12 is principally made of aluminum or aluminum-alloy, and the metal plug 14 is principally made of tungsten, wherein the patterned metal layer 12 is an aluminum-containing layer having a thickness of less than 3 μm (such as between 0.2 and 2 μm).

The patterned metal layer 12 may be formed by a process including sputtering an adhesion/barrier layer with a thickness of between 500 and 1 500 angstroms on an insulating layer, such as silicon oxide, next sputtering an aluminum-alloy layer, containing more than 90 wt. % of aluminum and less than 10 wt. % of copper, having a thickness between 0.2 and 2 micrometers on the adhesion/barrier layer, next sputtering an anti-reflection layer, such as a titanium-nitride layer, with a thickness of between 200 and 600 angstroms on the aluminum-alloy layer, next forming a photoresist layer on the anti-reflection layer, next patterning the photoresist layer using a photolithography process, next etching the adhesion/barrier layer, the aluminum-alloy layer and the anti-reflection layer not under the patterned photoresist layer using the patterned photoresist layer as an etching mask, and then removing the patterned photoresist layer. The material of the adhesion/barrier layer may include titanium, titanium nitride, a titanium-tungsten alloy, tantalum, tantalum nitride, or a composite of the abovementioned materials.

The dielectric layers 8 are located over the semiconductor substrate 4 and interposed respectively between the neighboring patterned metal layers 12, and the neighboring patterned metal layers 12 are interconnected through the metal plugs 14 inside the dielectric layer 8. The dielectric layer 8 is commonly formed by a chemical vapor deposition (CVD) process. The material of the dielectric layer 8 may include silicon oxide. The dielectric layer 8 between the neighboring patterned metal layers 12 has a thickness t2 of less than 3 micrometers, such as between 0.3 and 3 μm or between 0.3 and 2.5 μm.

The passivation layer 10 is formed over the metallization structure and over the dielectric layers 8. The passivation layer 10 can protect the semiconductor devices 6 and the metallization structure from being damaged by moisture and foreign ion contamination. In other words, mobile ions (such as sodium ion), transition metals (such as gold, silver and copper) and impurities can be prevented from penetrating through the passivation layer 10 to the semiconductor devices 6, such as transistors, polysilicon resistor elements and polysilicon-polysilicon capacitor elements, and to the metallization structure.

The passivation layer 10 is commonly made of silicon oxide (such as SiO₂), silicon oxynitride or silicon nitride (such as Si₃N₄). The passivation layer 10 on a pad 16 of the metallization structure and on the topmost metal layer 12 of the metallization structure commonly has a thickness t3 of more than 0.3 μm, such as between 0.3 and 2 μm. For example, the passivation layer 10 can be formed by depositing a silicon oxide layer with a thickness of between 0.2 and 1.2 μm using a CVD method and then depositing a silicon nitride layer with a thickness of 0.2 and 1.2 μm on the silicon oxide layer using a CVD method.

An opening 10a in the passivation layer 10 exposes a pad 16 of the metallization structure used to input or output signals or to be connected to a power source or a ground reference. In practical, a plurality of the openings 10a can be formed in the passivation layer 10, exposing a plurality of the pads 16, respectively. The pad 16 may have a thickness t4 of between 0.4 and 3 μm or between 0.2 and 2 μm, and the pad 16 is connected to the semiconductor device 6 through the metal layers 12 and the metal plugs 14.

The semiconductor substrate 4, the metallization structure, the dielectric layer 8, the passivation layer 10 and the pad 16 are described in the above paragraphs. Below, the integrated circuit (IC) scheme 20 under the passivation layer 10 may be the structure shown in FIG. 1 under the passivation layer 10; the IC scheme 20 represents the combination of the semiconductor substrate 4, the semiconductor devices 6, the metallization structure (including the metal layers 12 and the metal plugs 14) and the dielectric layers 8 in FIG. 1.

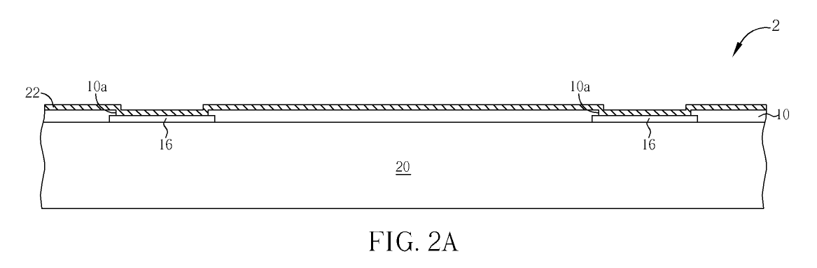

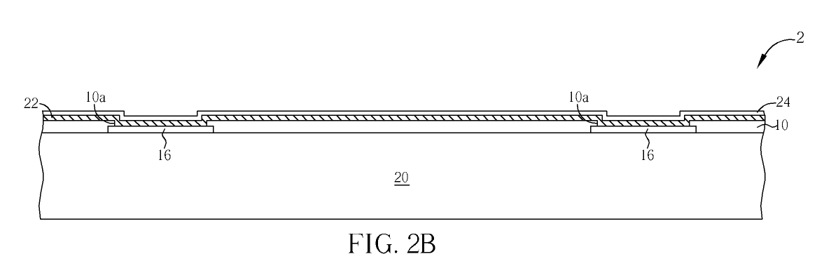

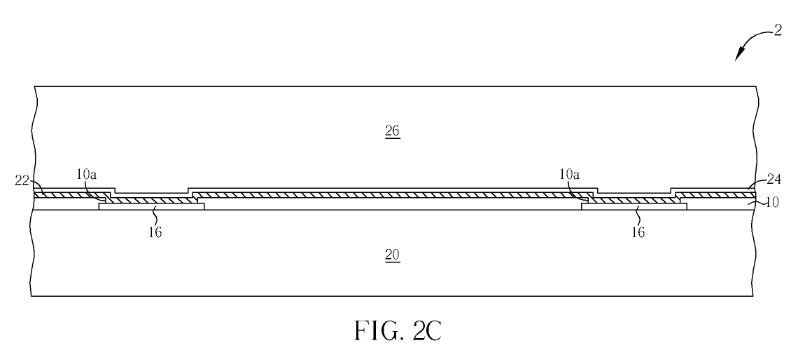

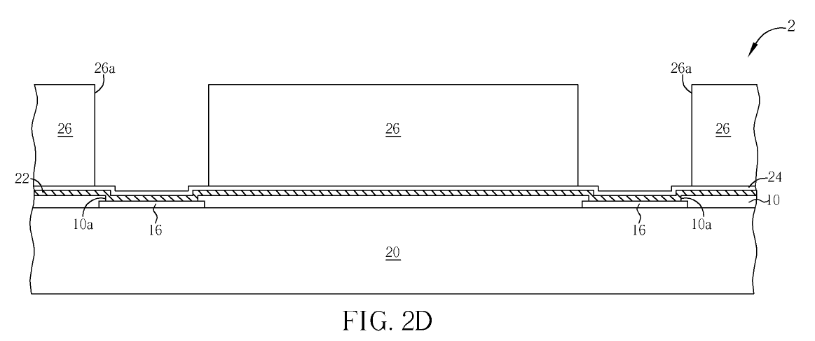

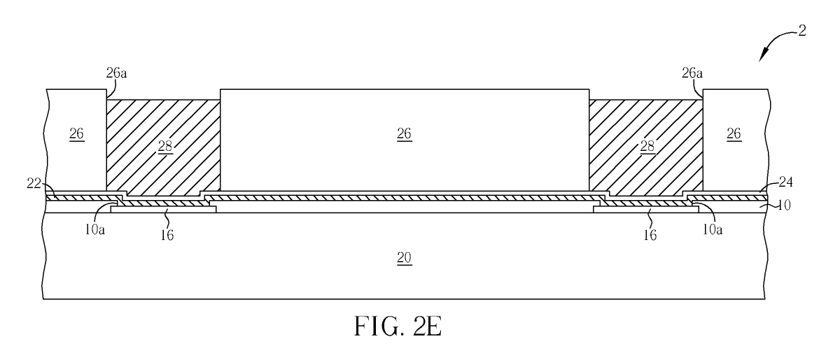

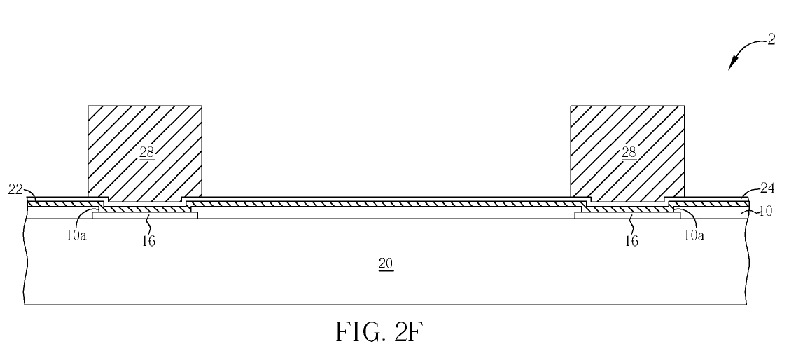

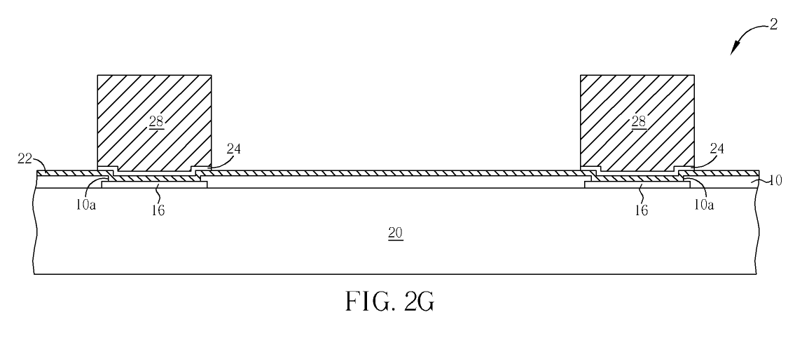

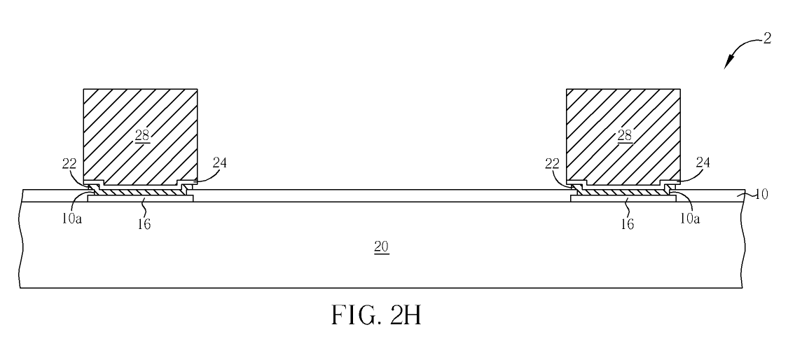

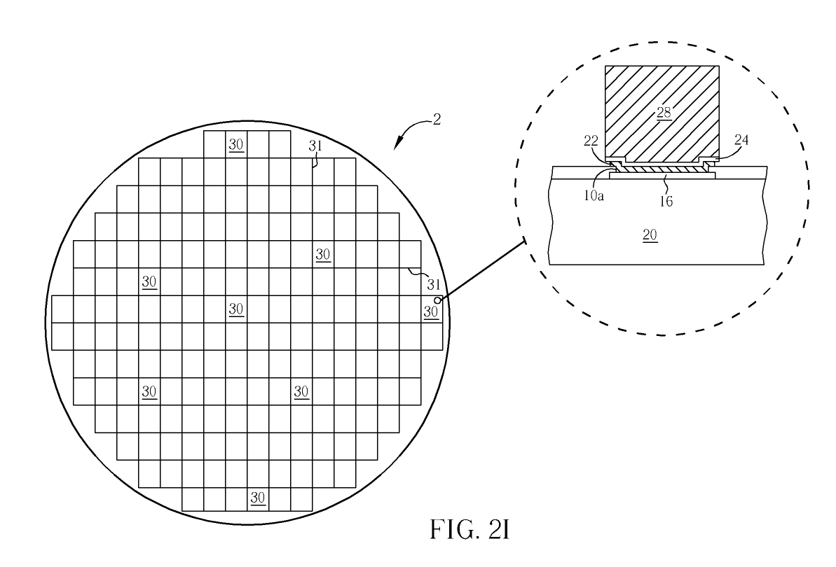

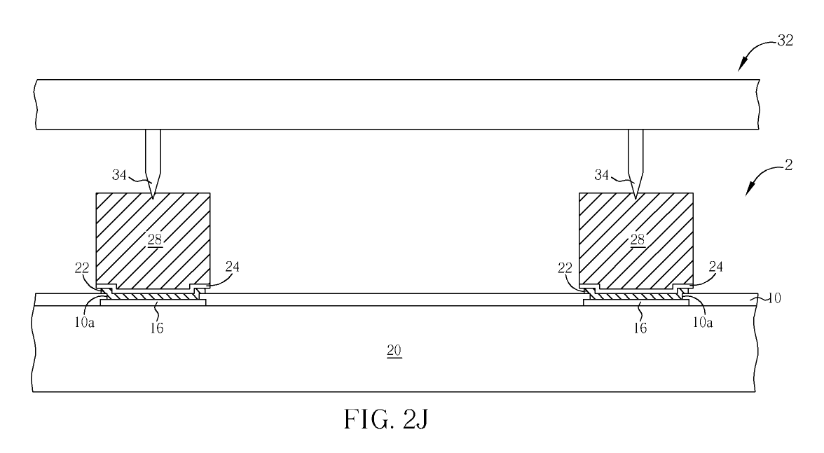

Referring to FIG. 2A, a titanium-tungsten-alloy layer 22 having a thickness of between 0.1 and 0.5 μm can be sputtered on the passivation layer 10 and on the pads 16 exposed, respectively, by the openings 10a. The titanium-tungsten-alloy layer 22 is treated as an adhesion/barrier layer to prevent the occurrence of interdiffusion between metal layers and to provide good adhesion between the metal layers.

Referring to FIG. 2B, a seed layer 24, made of gold, having a thickness of between 0.05 and 0.2 μm can be sputtered on the titanium-tungsten-alloy layer 22. Alternatively, the seed layer 24 can be formed by a vapor deposition method or a physical vapor deposition (PVD) method. The seed layer 24 is beneficial to electroplating a metal layer thereon.

Referring to FIG. 2C, a photoresist layer 26, such as positive-type photoresist layer, having a thickness of between 10 and 40 μm, and preferably of between 15 and 30 μm, is spin-on coated on the seed layer 24. Referring to FIG. 2D, the photoresist layer 26 is patterned with the processes of exposure and development to form openings 26a (only two of them are shown) in the photoresist layer 26 exposing the seed layer 24. A 1X stepper or 1X contact aligner can be used to expose the photoresist layer 26 during the process of exposure.

Referring to FIG. 2E, multiple gold bumps 28 (only two of them are shown) having a thickness of between 9 and 30 micrometers, and preferably of between 12 and 25 micrometers, are electroplated, respectively, on the seed layer 24 exposed by the openings 26a. For example, the gold bumps 28 can be formed by electroplating a gold layer having a thickness of between 9 and 30 micrometers, and preferably of between 12 and 25 micrometers, on the seed layer 24 exposed by the openings 26a.

Referring to FIG. 2F, after the gold bumps 28 are formed, the photoresist layer 26 can be removed using an organic solution with amide.

Referring to FIG. 2G, the seed layer 24 not under the gold bumps 28 can be removed with a dry etching method or a wet etching method. As to the wet etching method, the seed layer 24, made of gold, can be etched with an iodine-containing solution, such as solution containing potassium iodide. As to the dry etching method, the seed layer 24, made of gold, can be removed with an Ar sputtering etching process.

Referring to FIG. 2H, the titanium-tungsten-alloy layer 22 not under the gold bumps 28 can be removed with a wet etching method. Two methods for removing the titanium-tungsten-alloy layer 22 not under the gold bumps 28 are described as below:

In a first method, the semiconductor wafer 2 shown in FIG. 2G can be immersed in an etchant containing hydrogen peroxide at a temperature of between 35 and 50 degrees C., and preferably of between 38 and 42 degrees C., such as 40 degrees C., for a time of between 3 and 20 minutes, and preferably of between 5 and 15 minutes, to etch the titanium-tungsten-alloy layer 22 not under the gold bumps 28 with circulation flow. Alternatively, the semiconductor wafer 2 shown in FIG. 2G can be immersed in an etchant containing hydrogen peroxide at a temperature of between 43 and 47 degrees C., and preferably of 45 degrees C., for a time of between 3 and 20 minutes, and preferably of between 5 and 15 minutes, to etch the titanium-tungsten-alloy layer 22 not under the gold bumps 28 with circulation flow. The method has a high etching rate and can improve the etching behavior to prevent the titanium oxide and tungsten oxide from drifting onto the gold bumps 28 with the hydrodynamic circulation flow. Therefore, the frequency of probe cleaning during a chip probing (CP) test and of a CP re-test can be reduced due to the gold bumps 28 having clean surface.

In a secnod method, the semiconductor wafer 2 shown in FIG. 2G can be immersed in an etchant containing hydrogen peroxide at a temperature of between 23 and 27 degrees C., and preferably of 25 degrees C., for a time of between 10 and 50 minutes, and preferably of between 15 and 40 minutes, to etch the titanium-tungsten-alloy layer 22 not under the gold bumps 28 with circulation flow, and ultrasonic waves are applied to the etchant in the entire etching process or in a selected time interval between 5 and 10 minutes at the final period of the etching process. The ultrasonic waves having a fixed frequency selected from a frequency range between 28K Hz and 120K Hz are used here. The ultrasonic waves have a power of between 1.0 KW and 2.0 KW, and preferably of 1.5 KW. The method can prevent the titanium oxide and tungsten oxide from drifting onto the gold bumps 28 with the hydrodynamic circulation flow. Therefore, the frequency of probe cleaning during a chip probing (CP) test and of a CP re-test can be reduced due to the gold bumps 28 having clean surface.

Thereby, in the present invention, the gold bumps 28 can be formed, respectively, over the pads 16 exposed by the openings 10a and the titanium oxide and tungsten oxide, remaining on the gold bumps 28, can be reduced.

Referring to FIG. 2I, the semiconductor wafer 2 includes multiple dies 30 with scribe lines 31 between neighboring two of the dies 30. In the following wafer dicing process, the semiconductor wafer 2 can be cut along the scribe lines 31 to separate the dies 30. Each of the dies 30 may have the gold bumps 28, respectively, over the pads 16 exposed by the openings 10a.

Referring to FIGS. 2I and 2J, after etching the titanium-tungsten-alloy layer 22 not under the gold bumps 28, a chip probing (CP) test can be performed to electrically test all dies 30 of the semiconductior wafer 2 shown in FIG. 2H by contacting multiples probe tips 34 of a probe card 32 with some of the gold bumps 28 of the semiconductor wafer 2, in sequence, until the probe tips 34 of the probe card 32 have contacted with the entire gold bumps 28 provided by the semiconductor wafer 2. The probe tips 34 can contact with the entire gold bumps 28 provided by one of the dies 30 of the semiconductor wafer 2 once, or the probe tips 34 can contact with the entire gold bumps 28 provided by at least two of the dies 30 of the semiconductor wafer 2 once. The probe card 32 can be a vertical probe card, that is, the probe tips 34 can vertically contact with top surfaces of the gold bumps 28. The material of the probe tips 34 may include tungsten or rhenium.

Therefore, all dies 30 of the semiconductor wafer 2 can be electrically tested by contacting the probe tips 34 of the probe card 32 with the entire gold bumps 28 provided by one or more than one of the dies 30 once, until the probe tips 34 of the probe card 32 have contacted with the entire gold bumps 28 provided by the semiconductor wafer 2. The electrically testing process comprises following steps:

Step 1: the probe tips 34 of the probe card 32 probe the entire gold bumps 28 provided by one or more than one of the dies 30 of the semiconductor wafer 2 to electrically test the probed die or dies 30;

Step 2: the probe tips 34 of the probe card 32 probe the entire gold bumps 28 provided by another one or more than another one of the dies 30 of the semiconductor wafer 2 to electrically test the probed die or dies 30;

Step 3: the probe tips 34 of the probe card 32 are cleaned until the probe tips 34 probe the gold bumps 28 provided by the semiconductor wafer 2 at greater than 100 times, 150 times or even 200 times for electrically testing the respective dies 30 of the semiconductor wafer 2;

Step 4: after cleaning the probe tips 34 of the probe card 32, the probe tips 34 of the probe card 32 probe the gold bumps 28 provided by the other untested dies 30 of the semiconductor wafer 2; and

Step 5: repeating the step 3 and step 4 until all of the dies 30 of the semiconductor wafer 2 have been electrically tested using the probe card 32.

The probe tips 34 of the probe card 32 may be cleaned by a cleaning sheet to remove metal oxide, such as titanium oxide or tungsten oxide, adhered to the probe tips 34.

In the present invention, the residual of titanium oxide and tungsten oxide remaining on the gold bumps 28 of the semiconductor wafer 2 can be reduced using the two above-mention methods for removing the titanium-tungsten-alloy layer 22 not under the gold bumps 28. Thereby, the probe tips 34 of the probe card 32 should be cleaned only until the probe tips 34 of the probe card 32 contact with the gold bumps 28 provided by the semiconductor wafer 2 at greater than 100 times, 150 times or even 200 times. The invention can reduce the frequency of cleaning the probe tips 34 on the probe card 32 during a chip probing (CP) test and reduce the frequency of a CP re-test.

After the chip probing (CP) test, the semiconductor wafer 2 can be cut along the scribe lines 31 into multiple individual semiconductor chips 30, integrated circuit chips.

Those described above are the embodiments to exemplify the present invention to enable the person skilled in the art to understand, make and use the present invention. However, it is not intended to limit the scope of the present invention. Any equivalent modification and variation according to the spirit of the present invention is to be also included within the scope of the claims stated below.

What is claimed is:

1. A method for fabricating and testing a semiconductor wafer, comprising:
providing a silicon substrate, multiple metal oxide semiconductor (MOS) devices in or over said silicon substrate, a first dielectric layer over said silicon substrate, a metallization structure over said first dielectric layer, wherein said metallization structure comprises a first metal layer and a second metal layer over said first metal layer, and wherein said metallization structure is connected to said multiple metal oxide semiconductor devices, a second dielectric layer between said first and second metal layers, and a passivation layer over said metallization structure, over said first and second dielectric layers and over said multiple metal oxide semiconductor devices, multiple first openings in said passivation layer exposing multiple pads of said metallization structure, respectively;
sputtering a titanium-tungsten-alloy layer on said passivation layer and over said multiple pads exposed by said multiple first openings;
sputtering a gold layer on said titanium-tungsten-alloy layer;
forming a photoresist layer on said gold layer, multiple second openings in said photoresist layer exposing said gold layer;
electroplating multiple gold bumps with a thickness of between 9 and 30 micrometers on said gold layer exposed by said multiple second openings;
removing said photoresist layer;
removing said gold layer not under said multiple gold bumps;
etching said titanium-tungsten-alloy layer not under said multiple gold bumps with an etchant containing hydrogen peroxide at a temperature of between 35 and 50 degrees C.;
contacting multiple probe tips of a probe card with some of said multiple gold bumps to probe said semiconductor wafer;
cleaning said multiple probe tips of said probe card until repeating the step of said contacting said multiple probe tips of said probe card with some of said multiple gold bumps at greater than 100 times; and
after said cleaning said probe tips of said probe card, repeating the step of said contacting said multiple probe tips of said probe card with some of said multiple gold bumps.

2. The method of claim 1, wherein said titanium-tungsten-alloy layer has a thickness of between 0.1 and 0.5 micrometers.

3. The method of claim 1, wherein said gold layer has a thickness of between 0.05 and 0.2 micrometers.

4. The method of claim 1, wherein said electroplating said multiple gold bumps comprises said electroplating said multiple gold bumps with a thickness of between 12 and 25 micrometers on said gold layer exposed by said multiple second openings.

5. The method of claim 1, wherein said etching said titanium-tungsten-alloy layer comprises said etching said titanium-tungsten-alloy layer not under said multiple gold bumps with said etchant at a temperature of between 38 and 42 degrees C.

6. The method of claim 1, wherein said etching said titanium-tungsten-alloy layer comprises said etching said titanium-tungsten-alloy layer not under said multiple gold bumps with said etchant for a time of between 5 and 15 minutes.

7. The method of claim 1, wherein said passivation layer comprises nitride.

8. The method of claim 1, wherein said removing said gold layer comprises etching said gold layer not under said multiple gold bumps with a solution containing potassium iodide.

9. The method of claim 1, wherein said cleaning said multiple probe tips comprises said cleaning said multiple probe tips until repeating the step of said contacting said multiple probe tips with some of said multiple gold bumps at greater than 150 times.

10. A method for fabricating and testing a semiconductor wafer, comprising:
providing a silicon substrate, multiple metal oxide semiconductor (MOS) devices in or over said silicon substrate, a first dielectric layer over said silicon substrate, a metallization structure over said first dielectric layer, wherein said metallization structure comprises a first metal layer and a second metal layer over said first metal layer, and wherein said metallization structure is connected to said multiple metal oxide semiconductor devices, a second dielectric layer between said first and second metal layers, and a passivation layer over said metallization structure, over said first and second dielectric layers and over said multiple metal oxide semiconductor devices, multiple first openings in said passivation layer exposing multiple pads of said metallization structure, respectively;
sputtering a titanium-tungsten-alloy layer on said passivation layer and over said multiple pads exposed by said multiple first openings;
sputtering a gold layer on said titanium-tungsten-alloy layer;
forming a photoresist layer on said gold layer, multiple second openings in said photoresist layer exposing said gold layer;
electroplating multiple gold bumps with a thickness of between 9 and 30 micrometers on said gold layer exposed by said multiple second openings;
removing said photoresist layer;
removing said gold layer not under said multiple gold bumps;
etching said titanium-tungsten-alloy layer not under said multiple gold bumps with an etchant containing hydrogen peroxide and with an ultrasonic wave applied to said etchant;
contacting multiple probe tips of a probe card with some of said multiple gold bumps to probe said semiconductor wafer;
cleaning said multiple probe tips of said probe card until repeating the step of said contacting said multiple probe tips of said probe card with some of said multiple gold bumps at greater than 100 times; and
after said cleaning said probe tips of said probe card, repeating the step of said contacting said multiple probe tips of said probe card with some of said multiple gold bumps.

11. The method of claim 10, wherein said titanium-tungsten-alloy layer has a thickness of between 0.1 and 0.5 micrometers.

12. The method of claim 10, wherein said gold layer has a thickness of between 0.05 and 0.2 micrometers.

13. The method of claim 10, wherein said electroplating said multiple gold bumps comprises said electroplating said multiple gold bumps with a thickness of between 12 and 25 micrometers on said gold layer exposed by said multiple second openings.

14. The method of claim 10, wherein said etching said titanium-tungsten-alloy layer comprises said etching said titanium-tungsten-alloy layer not under said multiple gold bumps with said etchant at a temperature of between 23 and 27 degrees C.

15. The method of claim 10, wherein said etching said titanium-tungsten-alloy layer comprises said etching said titanium-tungsten-alloy layer not under said multiple gold bumps with said etchant for a time of between 15 and 40 minutes.

16. The method of claim 10, wherein said passivation layer comprises nitride.

17. The method of claim 10, wherein said removing said gold layer comprises etching said gold layer not under said multiple gold bumps with a solution containing potassium iodide.

18. The method of claim 10, wherein said ultrasonic wave has a frequency of between 28K Hz and 120K Hz.

19. The method of claim 10, wherein said ultrasonic wave has a power of 1.5 KW.

20. The method of claim 10, wherein said cleaning said multiple probe tips comprises said cleaning said multiple probe tips until repeating the step of said contacting said multiple probe tips with some of said multiple gold bumps at greater than 150 times.
